(19) United States
(12) Patent Application Publication
(10) Pub. No.: US 2007/0258227 A1
(43) Pub. Date: Nov. 8, 2007

(54) Method and apparatus for coupling a board to a chassis

(75) Inventors: Vibora Sim, Pflugerville, TX (US); Mark M. Bailey, Burnet, TX (US)

Correspondence Address: HAYNES AND BOONE, LLP, 901 MAIN STREET, SUITE 3100, DALLAS, TX, 75202, US

(73) Assignee: Dell Products L.P., Round Rock, TX (US)

(21) Appl. No.: 11/430,377

(22) Filed: May 8, 2006

(51) Int. Cl. H05K 7/14; H05K 7/18

(52) U.S. Cl. 361/801

(57) ABSTRACT

A board coupling apparatus includes a base including a board coupling side and defining a rod passageway. A rod is moveably coupled to the base and located in the rod passageway, whereby the rod is resiliently biased such that the rod extends from the board coupling side of the base. A board retaining member extends from the base and is located adjacent the board coupling side of the base, whereby the board retaining member is located in a spaced apart orientation from the rod passageway and the rod. The board coupling apparatus may be part of a chassis and used to couple a board to the chassis and restrict the boards movement in a first, second, and third axis.

### BACKGROUND

The present disclosure relates generally to information handling systems, and more particularly to coupling a board to an information handling system chassis.

As the value and use of information continues to increase, individuals and businesses seek additional ways to process and store information. One option is an information handling system (‘IHS’). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Conventional IHSs typically include a board that may include different component of the IHS. The board is generally coupled to an IHS chassis for use with the IHS. The coupling of the board to the IHS chassis raises a number of issues.

Typically, some boards may be coupled to the IHS chassis through a resiliently biased rod included on the IHS chassis. The resiliently biased rod may be positioned in an aperture defined by the board in order to secure the board to the chassis.

However, the positioning of the resiliently biased rod in the aperture defined by the board only secures the board to the chassis in two axes. Flexing of the board in a third axis such as, for example, during normal stress or the coupling of a connector to the board, can cause the board to become unseated from the resiliently biased rod and cause the board to decouple from the IHS chassis.

Accordingly, it would be desirable to provide for coupling a board to a chassis absent the disadvantages as discussed above.

### SUMMARY

According to one embodiment, a board coupling apparatus includes a base including a board coupling side and defining a rod passageway, a rod moveably coupled to the base and located in the rod passageway, whereby the rod is resiliently biased such that the rod extends from the board coupling side of the base, and a board retaining member extending from the base and located adjacent the board coupling side of the base, whereby the board retaining member is located in a spaced apart orientation from the rod passageway and the rod.

### BRIEF DESCRIPTION OF THE DRAWINGS

FIG. 1 is a schematic view illustrating an embodiment of an IHS.

FIG. 2a is a perspective view illustrating an embodiment of a chassis including a board coupling apparatus.

FIG. 2b is a perspective view illustrating an embodiment of the board coupling apparatus on the chassis of FIG. 2a.

FIG. 2c is a cross sectional view illustrating an embodiment of the board coupling apparatus of FIG. 2b.

FIG. 3 is a perspective view illustrating an embodiment of a board used with the chassis and board coupling apparatus of FIGS. 2a, 2b, and 2c.

FIG. 4a is a flow chart illustrating an embodiment of a method for coupling a board to a chassis.

FIG. 4b is a perspective view illustrating an embodiment of the board of FIG. 3 being coupled to the chassis and board coupling apparatus of FIGS. 2a, 2b, and 2c.

FIG. 4c is a perspective view illustrating an embodiment of the board of FIG. 3 being coupled to the chassis and board coupling apparatus of FIGS. 2a, 2b, and 2c.

FIG. 4d is a cross sectional view illustrating an embodiment of the board of FIG. 3 being coupled to the chassis and board coupling apparatus of FIGS. 2a, 2b, and 2c.

FIG. 4e is a perspective view illustrating an embodiment of the board of FIG. 3 coupled to the chassis and board coupling apparatus of FIGS. 2a, 2b, and 2c.

FIG. 4f is a perspective view illustrating an embodiment of the board of FIG. 3 coupled to the chassis and board coupling apparatus of FIGS. 2a, 2b, and 2c.

FIG. 4g is a cross sectional view illustrating an embodiment of the board of FIG. 3 coupled to the chassis and board coupling apparatus of FIGS. 2a, 2b, and 2c.

FIG. 4h is a perspective view illustrating an embodiment of the board of FIG. 3 coupled to the chassis and board coupling apparatus of FIGS. 2a, 2b, and 2c with a plurality of cables connected to the board.

FIG. 5 is a perspective view illustrating an alternative embodiment of a board coupling apparatus.

FIG. 6 is a perspective view illustrating an alternative embodiment of a board.

FIG. 7 is a cross sectional view illustrating an embodiment of the board of FIG. 6 coupled to the board coupling apparatus of FIG. 5.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance,. functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

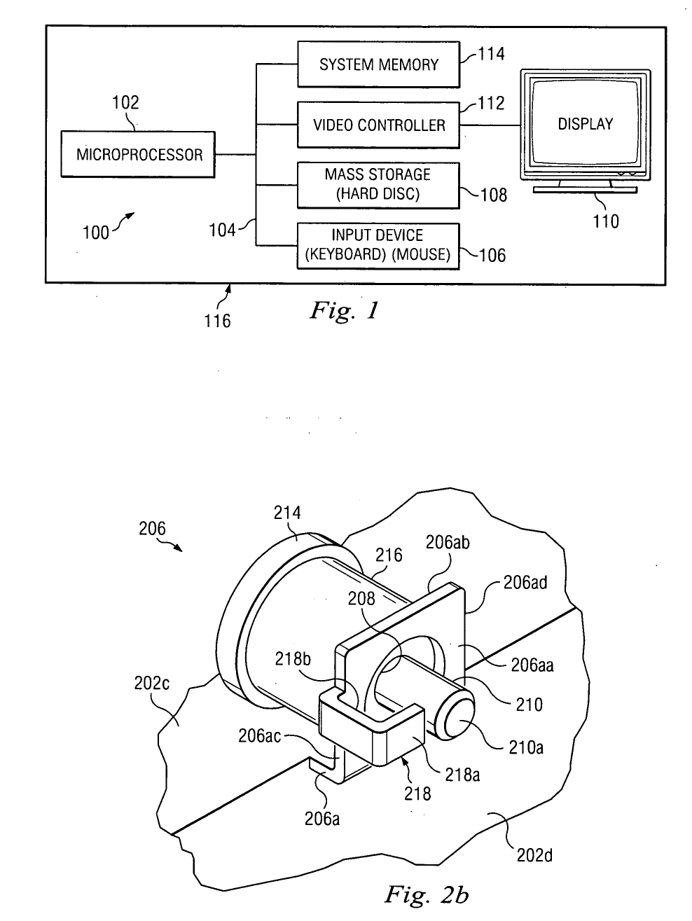

In one embodiment, IHS 100, FIG. 1, includes a microprocessor 102, which is connected to a bus 104. Bus 104 serves as a connection between microprocessor 102 and other components of computer system 100. An input device 106 is coupled to microprocessor 102 to provide input to microprocessor 102. Examples of input devices include keyboards, touchscreens, and pointing devices such as mouses, trackballs and trackpads. Programs and data are stored on a mass storage device 108, which is coupled to microprocessor 102. Mass storage devices include such devices as hard disks, optical disks, magneto-optical drives, floppy drives and the like. IHS 100 further includes a display 110, which is coupled to microprocessor 102 by a video controller 112. A system memory 114 is coupled to microprocessor 102 to provide the microprocessor with fast storage to facilitate execution of computer programs by microprocessor 102. In an embodiment, a chassis 116 houses some or all of the components of IHS 100. It should be understood that other buses and intermediate circuits can be deployed between the components described above and microprocessor 102 to facilitate interconnection between the components and the microprocessor.

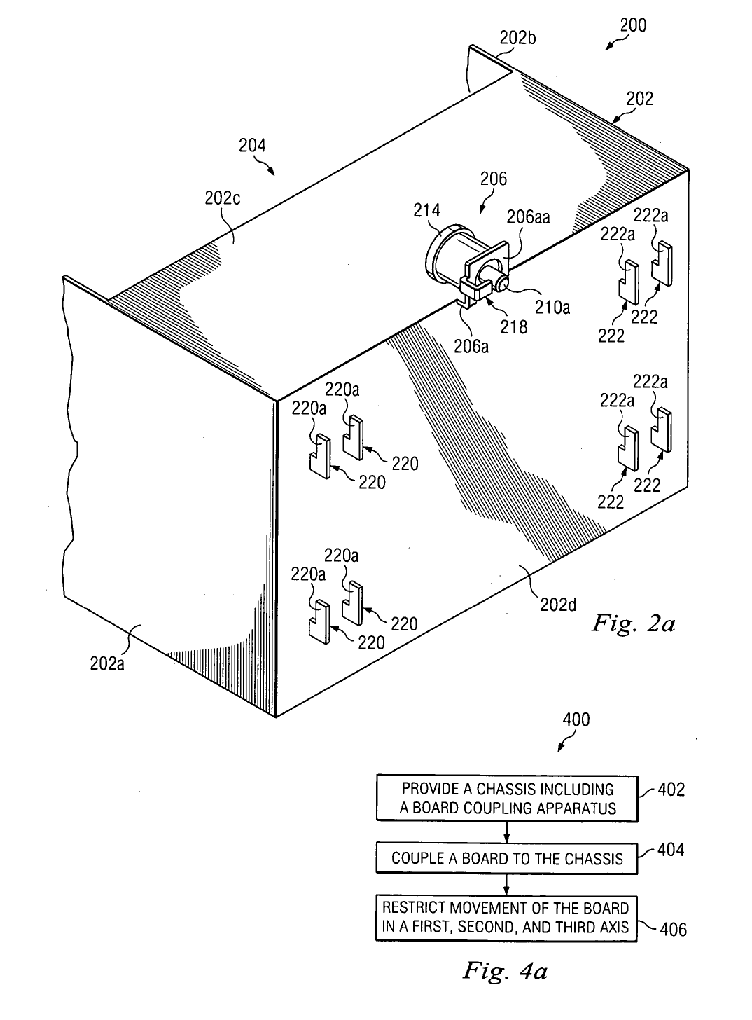

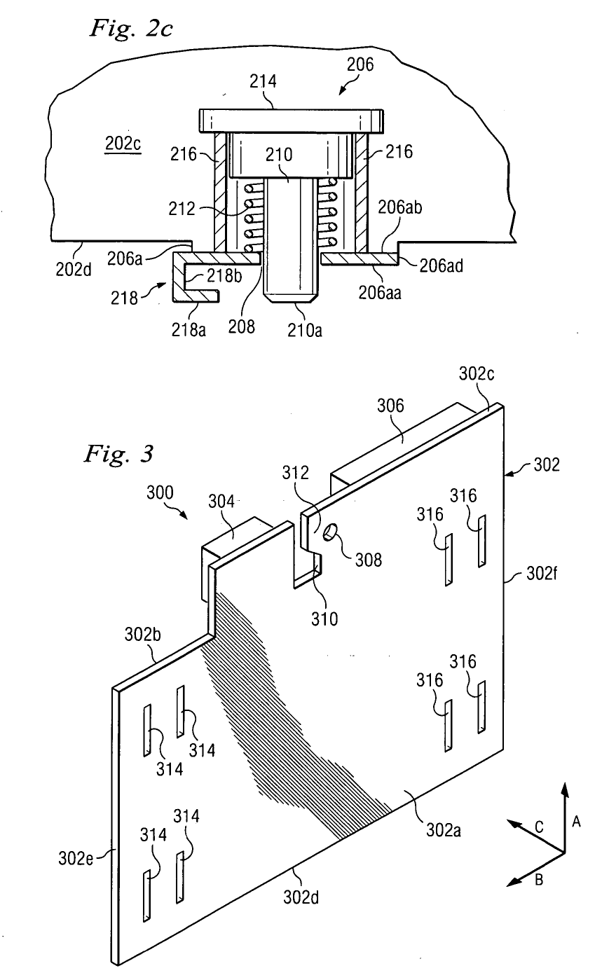

Referring now to FIGS. 2a, 2b, and 2c, a chassis 200 is illustrated. In an embodiment, the chassis 200 may be, for example, the chassis 116, described above with reference to FIG. 1, and may house some or all of the components of the IHS 100, described above with reference to FIG. 1. The chassis 200 includes a base 202 having a pair of opposing side surfaces 202a and 202b, a top surface 202c extending between the side surfaces 202a and 202b, and a front surface 202d extending between the side surfaces 202a and 202b and oriented substantially perpendicularly to the top surface 202c. The chassis 200 defines an IHS housing 204 between the side surfaces 202a and 202b, the top surface 202c, and the front surface 202d.

A board coupling apparatus 206 includes a base 206a extending from the front surface 202d of the chassis 200. The base 206a of the board coupling apparatus 206 includes a bend such that a portion of the base 206a is oriented substantially parallel to the front surface 202d of the chassis 200 and substantially perpendicular to the top surface 202c of the chassis 200. The base 206a of the board coupling apparatus 206 also includes a board coupling side 206aa, a rear surface 206ab located opposite the board coupling side 206aa, and a pair of opposing side surfaces 206ac and 206ad extending between the board coupling side 206aa and the rear surface 206ab. A rod passageway 208 is defined by and centrally located on the base 206 of the board coupling apparatus 206. A rod 210 including a rod distal end 210a is located in the rod passageway 208 and moveably coupled to the base 206 of the board coupling apparatus 206 by a spring 212 extending between the rod 210 and the rear surface 206ab of the base 206. The spring 212 resiliently biases the rod 210 such that a portion of the rod 210 including the rod distal end 210a extends from the board coupling side 206aa of the base 206. The rod 210 also includes a rod handle 214 located on the rod 210 opposite the rod distal end 210a. A rod support 216 extends from the rear surface 206ab of the base 206 of the board coupling apparatus 206 and engages the rod handle 214 when the rod 210 is resiliently biased to extend from the board coupling side 206aa of the base 206.

A board retaining member 218 extends from the side 206ac of the base 206 of the board coupling apparatus 206 and is located on the base 206 in a spaced apart orientation from the rod 210 and the rod passageway 208. In an embodiment, the board retaining member 218 includes a substantially U-shaped cross section, as illustrated in FIG. 2c, such that a portion 218a of the board retaining member 218 is located adjacent the board coupling side 206aa of the base 206 of the board coupling apparatus 206 and the board retaining member 218 defines a board retaining channel 218b adjacent the portion 218a of the board retaining member 218. A plurality of board coupling members 220 extend from the front surface 202d of the base 202 of the chassis 200 and are located adjacent the side surface 202a of the base 202 of the chassis 200, each board coupling member 220 including a securing beam 220a. A plurality of board coupling members 222 extend from the front surface 202d of the base 202 of the chassis 200 and are located adjacent the side surface 202b of the base 202 of the chassis 200, each board coupling member 222 including a securing beam 222a.

Referring now to FIG. 3, a board 300 is illustrated. The board 300 includes a base 302 having a front surface 302a, a rear surface 302b located opposite the front surface 302a, a top surface 302c extending between the front surface 302a and the rear surface 302b, a bottom surface 302d located opposite the top surface 302c and extending between the front surface 302a and the rear surface 302b, and a pair of side surface 302e and 302f extending between the front surface 302a, the rear surface 302b, the top surface 302c, and the bottom surface 302d. In an embodiment, the board 300 has a first axis A that is substantially parallel to the side surfaces 302e and 302f, a second axis B that is substantially parallel to the top surface 302c and the bottom surface 302d, and a third axis C that is substantially perpendicular to the first axis A and the second axis B. A plurality of connectors 304 and 306 extend from the rear surface 302b of the board 300 and are located adjacent the top surface 302c of the board 300. A rod aperture 308 is defined by the base 302, extends through the base 302 from the front surface 302a to the rear surface 302b, and is substantially centrally located on the board 300 adjacent the top surface 302c. A retaining member channel 310 is defined by the base 302 and is located adjacent the rod aperture 308 and the top surface 302c of the board 300. A retaining member engagement surface 312 is located on the front surface 302a of the board 300 adjacent the retaining member channel 310 and the top surface 302c of the board 300. A plurality of board coupling member apertures 314 are defined by the base 302, extend through the base 302 from the front surface 302a to the rear surface 302b, and are located adjacent the side surface 302e of the board 300. A plurality of board coupling member apertures 316 are defined by the base 302, extend through the base 302 from the front surface 302a to the rear surface 302b, and are located adjacent the side surface 302f of the board 300.

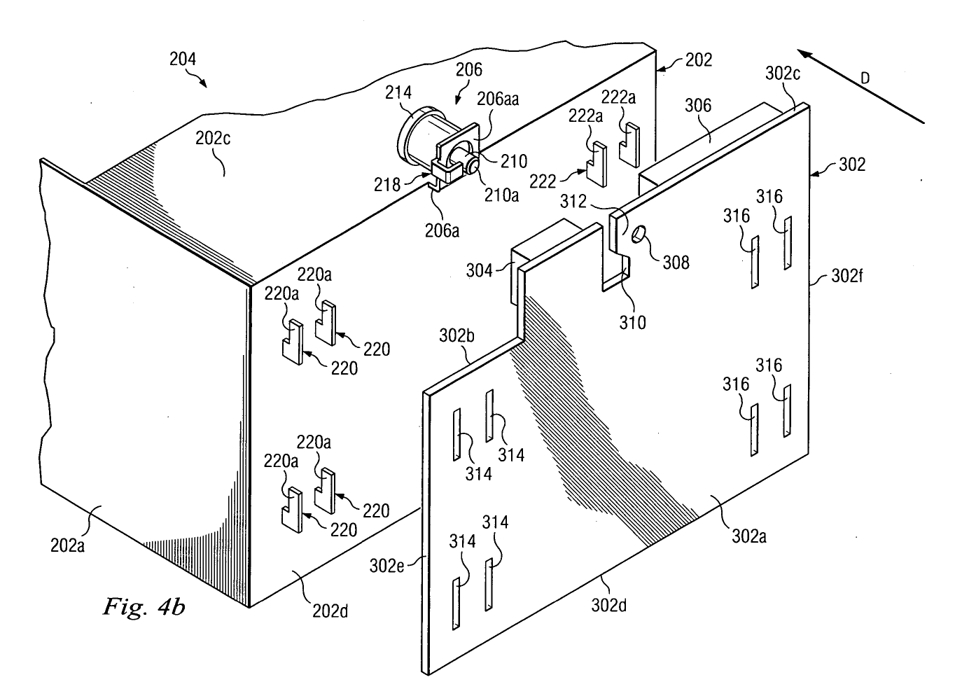

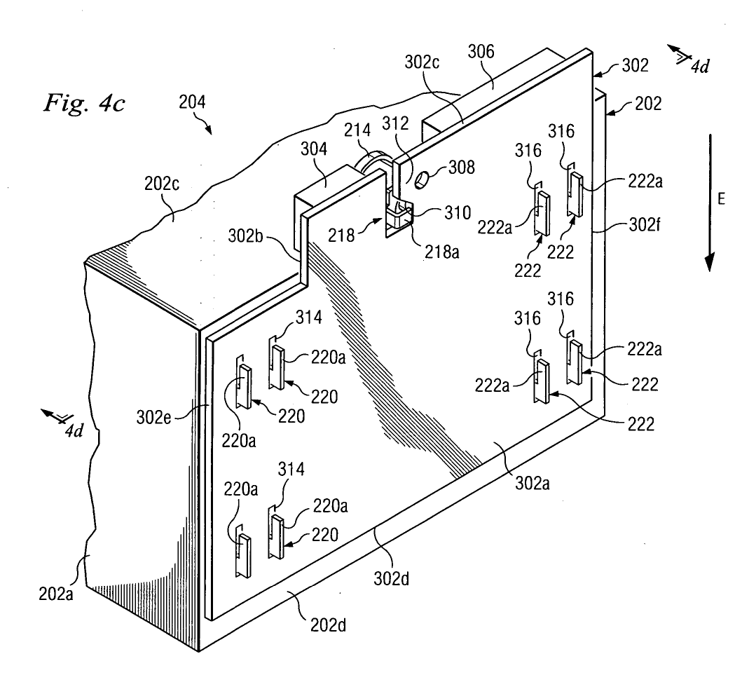

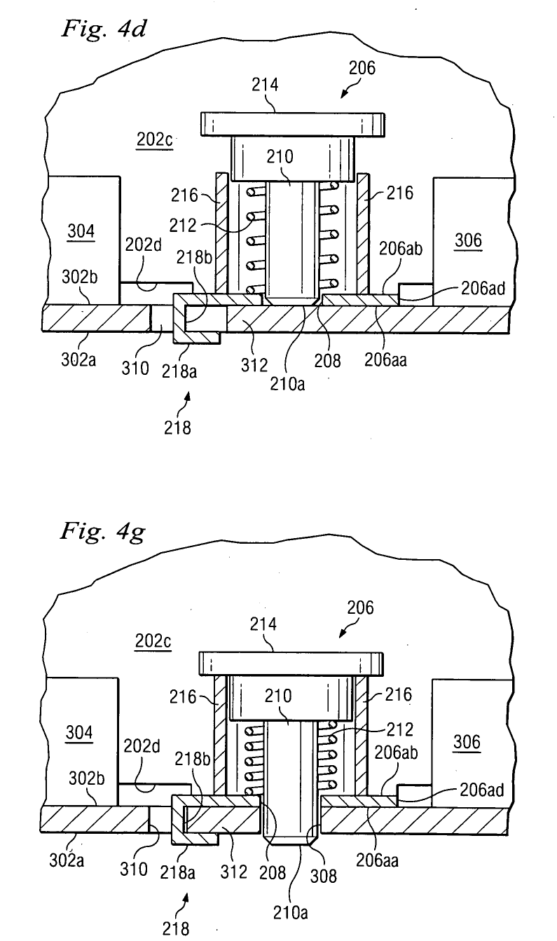

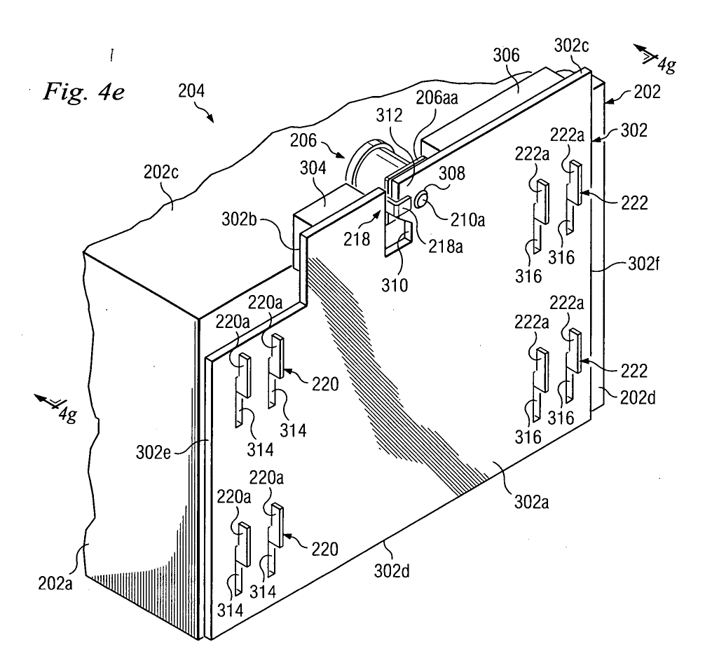

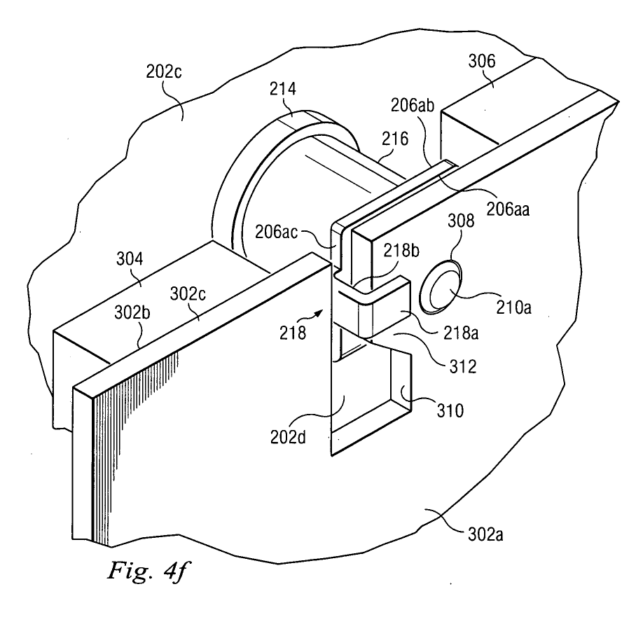

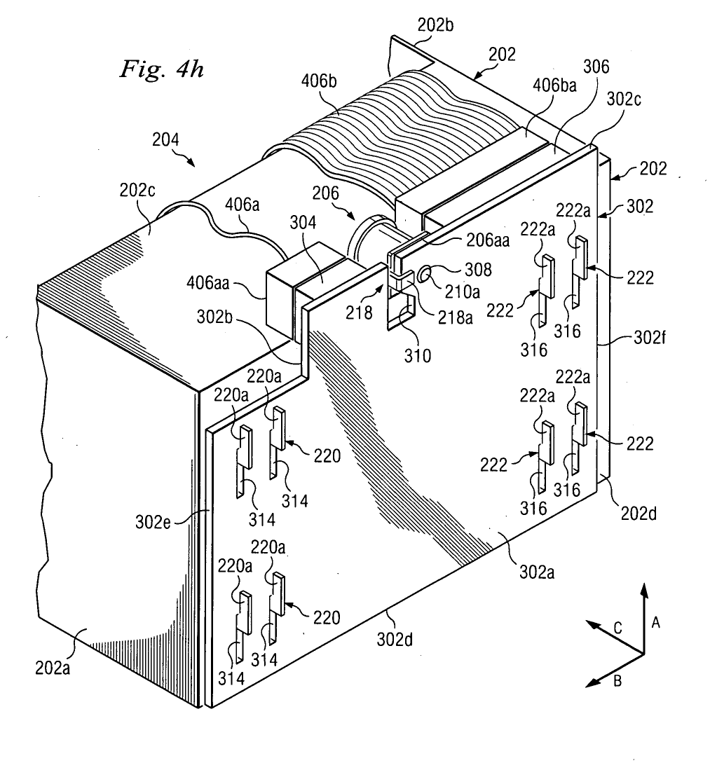

Referring now to FIGS. 2a, 2b, 2c, 3, 4a, 4b, 4c, 4d, 4e, 4f, and 4g, a method 400 for coupling a board to a chassis is illustrated. The method 400 begins at step 402 where the chassis 200 including the board coupling apparatus 206, illustrated in FIGS. 2a, 2b, and 2c, is provided. The method 400 then proceeds to step 404 where a board is coupled to the chassis. The board 300, illustrated in FIG. 3, is positioned adjacent the chassis 200 such that the rear surface 302b of the board 300 is located adjacent the front surface 202d of the chassis 200 with the board coupling member apertures 314 aligned with the board coupling members 220, the board coupling member apertures 316 aligned with the board coupling members 222, and the rod aperture 308 and the retaining member channel 310 located adjacent the board coupling apparatus 206, as illustrated in FIG. 4b.

The board 300 is then moved in a direction D such that the board coupling members 220 enter the board coupling member apertures 314, the board coupling members 222 enter the board coupling member apertures 316, the board retaining member 218 enters the retaining member channel 310, and the rear surface 302b of the board 300 engages the rod distal end 210a and moves the rod 210 through the rod passageway 208 such that the rod 210 no longer extends from the board coupling side 206aa of the base 206a of the board coupling apparatus 206, as illustrated in FIGS. 4c and 4d. The board 300 is then moved in a direction E, such that the board coupling members 220 move through the board coupling member apertures 314 and the securing beams 220a engage the front surface 302a of the board 300, the board coupling members 222 move through the board coupling member apertures 316 and the securing beams 222a engage the front surface 302a of the board 300, the board 300 enters the board retaining channel 218b defined by the board retaining member 218 and the portion 218a of the board retaining member 218 engages the retaining member engagement surface 312, and the rod 210 is resiliently biased into the rod aperture 208 defined by the board 300, securing the board 300 to the chassis, as illustrated in FIGS. 4e, 4f, and 4g.

Referring now to FIGS. 3, 4a, 4e, 4f, 4g, and 4h, the method 400 proceeds to step 406 where the movement of the board is restricted in a first, second, and third axis. With the securing beams 220a and 222a on board coupling members 220 and 222, respectively, engaging the front surface 302a of the board 300, the board 300 located in the board retaining channel 218b defined by the board retaining member 218 and the portion 218a of the board retaining member 218 engaging the retaining member engagement surface 312 on the board 300, and the rod 210 located in the rod aperture 308 defined by the board 300, the board 300 is secured to the chassis 200. The locating of the rod 210 in the rod aperture 308 restricts the board 300 from moving along the first axis A and the second axis B due to the engagement of the rod 210 and the base 302 of the board 300. The locating of the board 300 in the board retaining channel 218b and the engagement of the portion 218a of the board retaining member 218 with the retaining member engagement surface 312 on the board 300 restricts the board from moving in the third axis C. In an embodiment, a plurality of cables 406a and 406b, each including a connector 406aa and 406ba, respectively, may be run from an IHS located in the IHS housing 204 and coupled to the board 300 by engaging the connectors 406aa and 406ba with the connectors 304 and 306, respectively, as illustrated in FIG. 4h. In an embodiment, the cables 406a and 406b may be coupled to an IHS component such as, for example, a microprocessor. During the coupling of the cables 406a and 406b to the board 300, the restricting of movement of the board 300 in the third axis C by the engagement of the board retaining member 218 and the board 300 prevents the board 300 from decoupling from the rod 210 due to flexing of the board 300 away from the rod 210 as a result of the pressure applied when coupling connectors 406a and 406b to the connectors 304 and 306, respectively. The board 300 may be removed from the chassis 200 by using the rod handle 214 to move the rod 210 out of the rod aperture 308 defined by the board 300 such that the board 300 may be removed from the chassis 200 by removing the board coupling members 200 and 222 from the board coupling member apertures 314 and 316, respectively.

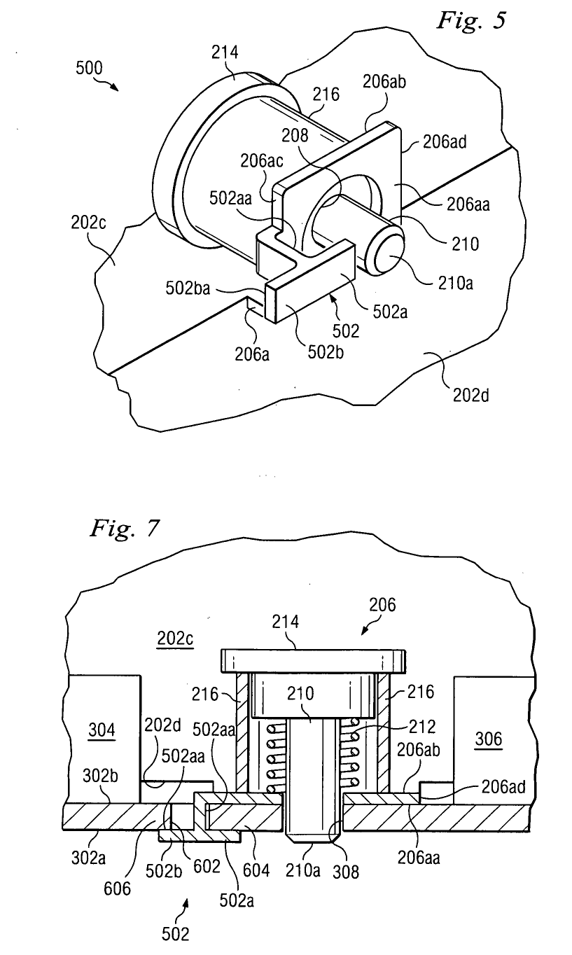

Referring now to FIG. 5, in an alternative embodiment, a board coupling apparatus 500 is substantially similar in design and operation to the board coupling apparatus 206, described above with reference to FIGS. 2a, 2b, 2c, 4a, 4b, 4c, 4d, 4e, 4f, 4g, and 4h, with the provision of a board retaining member 502 replacing the board retaining member 218. The board retaining member 502 extends from the side 206ac of the base 206 of the board coupling apparatus 500 and is located on the base 206 in a spaced apart orientation from the rod 210 and the rod passageway 208. In an embodiment, the board retaining member 502 includes a substantially T-shaped cross section, as illustrated in FIG. 5, such that a portion 502a of the board retaining member 502 is located adjacent the board coupling side 206aa of the base 206 of the board coupling apparatus 206 and the board retaining member 502 defines a board retaining channel 502aa adjacent the portion 502a of the board retaining member 502. Furthermore, a portion 502b of the board retaining member 502 extends opposite the portion 502a such that the board retaining member 502 defines a board retaining channel 502ba opposite the board retaining channel 502aa and adjacent the portion 502b of the board retaining member 502.

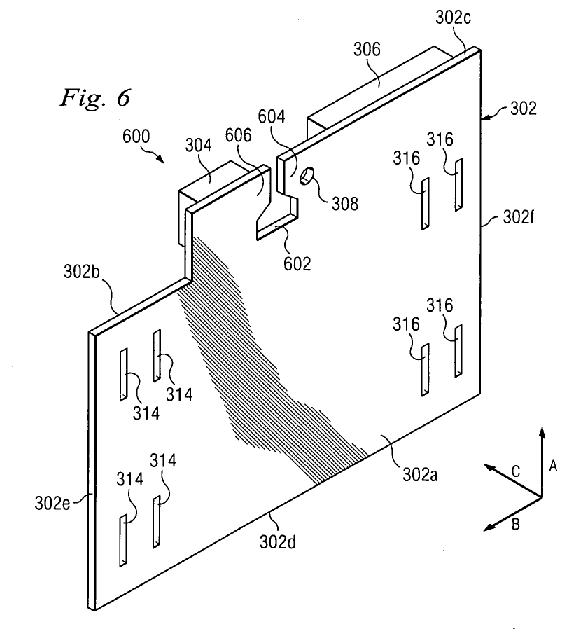

Referring now to FIG. 6, in an alternative embodiment, a board 600 is substantially similar in design and operation to the board 300, described above with reference to FIGS. 3, 4a, 4b, 4c, 4d, 4e, 4f, 4g, and 4h, with the provision of a retaining member channel 602 replacing the retaining member channel 310. The retaining member channel 310 is defined by the base 302 and is located adjacent the rod aperture 308 and the top surface 302c of the board 300. A retaining member engagement surface 604 and a retaining member engagement surface 606 are located adjacent the retaining member channel 602 and on opposite sides of the retaining channel 602.

Referring now to FIGS. 6 and 7, in operation, the board 600 may be coupled to the chassis 200 using the board coupling apparatus 500 in substantially the same manner as described above for coupling the board 300 to the chassis 200 using the board coupling apparatus 206. However, with the board 600 coupled to the board coupling apparatus 500, the portions 502a and 502b of the board retaining member 502 engage the retaining member engagement surfaces 604 and 606, respectively, on the board, providing additional support to restrict movement of the board 600 in the third axis C.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A board coupling apparatus, comprising:
a base comprising a board coupling side and defining a rod passageway;
a rod moveably coupled to the base and located in the rod passageway, whereby the rod is resiliently biased such that the rod extends from the board coupling side of the base; and
a board retaining member extending from the base and located adjacent the board coupling side of the base, whereby the board retaining member is located in a spaced apart orientation from the rod passageway and the rod.

2. The apparatus of claim 1, wherein the base extends from an information handling system chassis.

3. The apparatus of claim 1, wherein the rod includes a rod handle that is operable to move the rod relative to the base and through the rod passageway such that the rod does not extend from the board coupling side of the chassis.

4. The apparatus of claim 1, wherein the rod includes a spring which is coupled to the rod and the base, whereby the spring resiliently biases the rod such that the rod extends from the board coupling side of the base.

5. The apparatus of claim 1, wherein the board retaining member comprises a U-shaped cross section defining a board retaining channel.

6. The apparatus of claim 1, wherein the board retaining member comprises a T-shaped cross section defining a plurality of board retaining channels.

7. The apparatus of claim 1, further comprising:
a rod support extending from the base opposite the board retaining side, whereby the rod is operable to engage the rod support member to support the rod when the rod is resiliently biased such that the rod extends from the board coupling side of the base.

8. An information handling system, comprising:
a chassis,
a microprocessor coupled to the chassis;
a base extending from the chassis, wherein the base comprises a board coupling side and defines a rod passageway;
a rod moveably coupled to the base and located in the rod passageway, whereby the rod is resiliently biased such that the rod extends from the board coupling side of the base; and
a board retaining member extending from the base and located adjacent the board coupling side of the base, whereby the board retaining member is located in a spaced apart orientation from the rod passageway and the rod.

9. The system of claim 8, wherein the rod includes a rod handle that is operable to move the rod relative to the base and through the rod passageway such that the rod does not extend from the board coupling side of the chassis.

10. The system of claim 8, wherein the rod includes a spring which is coupled to the rod and the base, whereby the spring resiliently biases the rod such that the rod extends from the board coupling side of the base.

11. The system of claim 8, wherein the board retaining member comprises a U-shaped cross section defining a board retaining channel.

12. The system of claim 8, wherein the board retaining member comprises a T-shaped cross section defining a plurality of board retaining channels.

13. The system of claim 8, further comprising:
a rod support extending from the base opposite the board retaining side, whereby the rod is operable to engage the rod support member to support the rod when the rod is resiliently biased such that the rod extends from the board coupling side of the base.

14. The system of claim 8, further comprising:
a board defining a rod aperture coupled to the chassis, whereby the rod is positioned in the rod aperture to restrict movement of the board in a first axis and a second axis and the board retaining member engages the board to restrict movement of the board in a third axis.

15. The system of claim 14, further comprising:
a cable coupled to the board, whereby the cable couples the board to the microprocessor.

16. The system of claim 8, wherein the chassis comprises a plurality of board coupling members extending from the chassis.

17. The system of claim 16, further comprising:
a board defining a rod aperture and a plurality of coupling member apertures coupled to the chassis, whereby the rod is positioned in the rod aperture to restrict movement of the board in a first axis and a second axis, the board retaining member engages the board to restrict movement of the board in a third axis, and the plurality of board coupling members are located in the coupling member apertures to couple the board to the chassis.

18. A method for coupling a board to a chassis, comprising:
providing a chassis comprising a base extending from the chassis, a rod moveably coupled to the base, and a board retaining member extending from the base adjacent the rod;
coupling a board to the chassis by positioning the rod in a rod aperture defined by the board and engaging the board with the board retaining member; and
restricting movement of the board in a first axis and a second axis due to the positioning of the rod in the rod aperture and restricting movement of the board in a third axis due to the engagement of the board retaining member and the board.

19. The method of claim 18, wherein the chassis comprises a plurality of board coupling members extending from the chassis and the board defines a plurality of coupling member apertures, whereby the coupling the board to the chassis comprises engaging the board with the board coupling members by positioning the board coupling members in the coupling member apertures.

20. The method of claim 18, wherein the positioning the rod in the rod aperture comprises resiliently biasing the rod into the rod aperture.
